(19) United States
(12) Patent Application Publication
(10) Pub. No.: US 2007/0170517 A1
(43) Pub. Date: Jul. 26, 2007

(54) CMOS devices adapted to reduce latchup and methods of manufacturing the same

(75) Inventors: Toshiharu Furukawa, Essex Junction, VT (US); Charles W. Koburger III, Delmar, NY (US); Jack A. Mandelman, Flat Rock, NC (US)

Correspondence Address: IBM Corporation;Intellectual Property Law Dept. 917, 3605 Hwy. 52 North, Rochester, MN, 55901, US

(73) Assignee: International Business Machines Corporation, Armonk, NY (US)

(21) Appl. No.: 11/340,342

(22) Filed: Jan. 26, 2006

(51) Int. Cl. H01L 29/76

(52) U.S. Cl. 257/372

(57) ABSTRACT

In a first aspect, a first apparatus is provided. The first apparatus is semiconductor device that includes (1) a shallow trench isolation (STI) oxide region; (2) a first metal-oxide-semiconductor field-effect transistor (MOSFET) coupled to a first side of the STI oxide region; (3) a second MOSFET coupled to a second side of the STI oxide region, wherein portions of the first and second MOSFETs form first and second bipolar junction transistors (BJTs) which are coupled into a loop; and (4) a dopant-implanted region below the STI oxide region, wherein the dopant-implanted region forms a portion of the BJT loop and is adapted to reduce a gain of the loop. Numerous other aspects are provided.

### FIELD OF THE INVENTION

The present invention relates generally to semiconductor device manufacturing, and more particularly to CMOS devices adapted to reduce latchup and methods of manufacturing the same.

### BACKGROUND

Regions of a conventional complementary metal-oxide-semiconductor field-effect transistor (CMOS) device may serve as or form a plurality of bipolar junction transistors (BJTs) (e.g., coupled in a loop). For example, a conventional CMOS device may include a PFET adjacent a first side of a shallow trench isolation (STI) oxide region and an NFET adjacent a second side of the STI oxide region. Diffusion regions and/or wells of the NFET and PFET may form a first BJT coupled to a second BJT in a loop.

A particle that strikes the CMOS device, a voltage induced in the CMOS device and/or a similar occurrence may initiate a regenerative action and induce a current in the BJT loop. Due to a gain of the BJT loop, the current through the BJT loop may continue to increase until the device is destroyed (a condition referred to as “latchup”). Accordingly, improved CMOS devices that reduce latchup and methods of manufacturing the same are desired.

### SUMMARY OF THE INVENTION

In a first aspect of the invention, a first apparatus is provided. The first apparatus is a semiconductor device that includes (1) a shallow trench isolation (STI) oxide region; (2) a first metal-oxide-semiconductor field-effect transistor (MOSFET) coupled to a first side of the STI oxide region; (3) a second MOSFET coupled to a second side of the STI oxide region, wherein portions of the first and second MOSFETs form first and second bipolar junction transistors (BJTs) which are coupled into a loop; and (4) a dopant-implanted region below the STI oxide region, wherein the dopant-implanted region forms a portion of the BJT loop and is adapted to reduce a gain of the loop.

In a second aspect of the invention, a first system is provided. The first system is a substrate that includes (1) a bulk silicon layer; and (2) a semiconductor device, portions of which are formed in the bulk silicon layer, the semiconductor device having (a) a shallow trench isolation (STI) oxide region; (b) a first metal-oxide-semiconductor field-effect transistor (MOSFET) coupled to a first side of the STI oxide region; (c) a second MOSFET coupled to a second side of the STI oxide region, wherein portions of the first and second MOSFETs form first and second bipolar junction transistors (BJTs) which are coupled into a loop; and (d) a dopant-implanted region below the STI oxide region, wherein the dopant-implanted region forms a portion of the BJT loop and is adapted to reduce a gain of the loop.

In a third aspect of the invention, a first method of manufacturing a semiconductor device on a substrate is provided. The first method includes the steps of (1) forming a shallow trench isolation (STI) oxide region on the substrate; (2) forming a first metal-oxide-semiconductor field-effect transistor (MOSFET) coupled to a first side of the STI oxide region; (3) forming a second MOSFET coupled to a second side of the STI oxide region, wherein portions of the first and second MOSFETs form first and second bipolar junction transistors (BJTs) which are coupled into a loop; and (4) forming a dopant-implanted region below the STI oxide region, wherein the dopant-implanted region forms a portion of the BJT loop and is adapted to reduce a gain of the loop. Numerous other aspects are provided in accordance with these and other aspects of the invention.

Other features and aspects of the present invention will become more fully apparent from the following detailed description, the appended claims and the accompanying drawings.

### BRIEF DESCRIPTION OF THE FIGURES

FIG. 1 is a cross-sectional side view of a conventional CMOS device.

FIG. 2 illustrates a simulation of a CMOS device adapted to reduce latchup in accordance with an embodiment of the present invention.

FIG. 3 is a graph illustrating a relationship between current through a CMOS device adapted to reduce latchup and a voltage applied across the CMOS device in accordance with an embodiment of the invention.

FIG. 4 is a cross-sectional side view of a substrate following a first step of a method of manufacturing a first exemplary CMOS device adapted to reduce latchup in accordance with an embodiment of the present invention.

FIG. 5 is a cross-sectional side view of the substrate following a second step of the method of manufacturing the first exemplary CMOS device adapted to reduce latchup in accordance with an embodiment of the present invention.

FIG. 6 is a cross-sectional side view of the substrate following a third step of the method of manufacturing the first exemplary CMOS device adapted to reduce latchup in accordance with an embodiment of the present invention.

FIG. 7 is a cross-sectional side view of the substrate following a first step of a method of manufacturing a second exemplary CMOS device adapted to reduce latchup in accordance with an embodiment of the present invention.

FIG. 8 is a cross-sectional side view of the substrate following a second step of the method of manufacturing the second exemplary CMOS device adapted to reduce latchup in accordance with an embodiment of the present invention.

FIG. 9 is a cross-sectional side view of the substrate following a third step of the method of manufacturing the second exemplary CMOS device adapted to reduce latchup in accordance with an embodiment of the present invention.

FIG. 10 is a cross-sectional side view of the substrate following a first step of a method of manufacturing a third exemplary CMOS device adapted to reduce latchup in accordance with an embodiment of the present invention.

FIG. 11 is a cross-sectional side view of the substrate following a second step of the method of manufacturing the third exemplary CMOS device adapted to reduce latchup in accordance with an embodiment of the present invention.

FIG. 12 is a cross-sectional side view of the substrate following a third step of the method of manufacturing the third exemplary CMOS device adapted to reduce latchup in accordance with an embodiment of the present invention.

FIG. 13 is a cross-sectional side view of the substrate following a fourth step of the method of manufacturing the third exemplary CMOS device adapted to reduce latchup in accordance with an embodiment of the present invention.

FIG. 14 is a cross-sectional side view of the substrate following a fifth step of the method of manufacturing the third exemplary CMOS device adapted to reduce latchup in accordance with an embodiment of the present invention.

### DETAILED DESCRIPTION

The present invention provides improved CMOS devices and methods of manufacturing the same. More specifically, the present invention provides a CMOS device having a PFET adjacent a first side of a shallow trench isolation (STI) oxide region and an NFET adjacent a second side of the STI oxide region. However, in contrast to the conventional CMOS device, a CMOS device in accordance with an embodiment of the present invention provides an implanted N+ region or pocket below the STI oxide region. Such an implanted N+ region or pocket may serve to minimize regenerative action caused by a particle strike, an induced voltage, and/or a similar occurrence. For example, as current in the BJT loop passes through the N+ region or pocket, the N+ region or pocket may reduce a number of holes leaving therefrom. Consequently, the N+ region or pocket may reduce and/or prevent gain of current through the loop. Therefore, a voltage at which latchup is reached may be increased. Thus, by keeping a power supply voltage applied to the CMOS device below such increased voltage, the CMOS may avoid latchup while still operating at a voltage level that meets performance requirements of the CMOS device. In this manner, the present invention provides improved CMOS devices and methods of manufacturing the same.

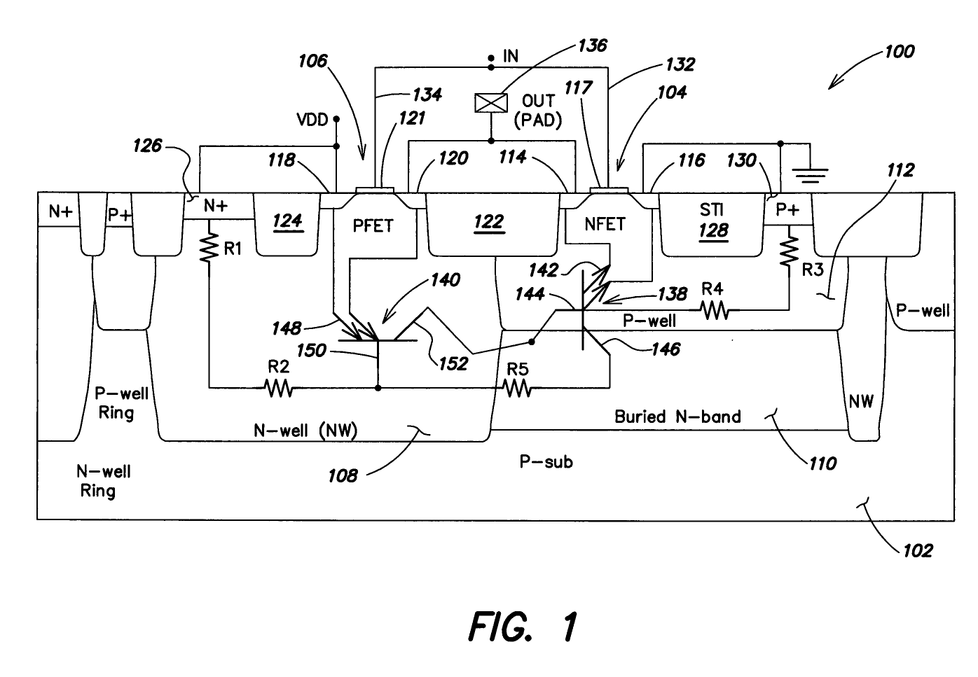

FIG. 1 is a conventional CMOS device 100. With reference to FIG. 1, the conventional CMOS device 100 may be formed on a bulk substrate 102. The CMOS device 100 may be an inverter having a first transistor, such as an n-channel MOSFET (NFET) 104, coupled to a second transistor, such as a p-channel MOSFET (PFET) 106. More specifically, the CMOS device 100 may include an N-well region 108, an adjacent buried N-band region 110 and a P-well region 112 above the buried N-band region 110 formed on the substrate 102 as found in a standard triple-well bulk CMOS structure. Alternatively, in some embodiments, the conventional CMOS device 100 may not include the buried N-band region 110.

First and second source/drain diffusion regions 114, 116 (e.g., N+ diffusion regions) of the NFET 104 may be formed on the P-well region 112 of the substrate 102. Further, a gate stack 117 may be formed between such diffusion regions 114, 116. Similarly, first and second source/drain diffusion regions 118, 120 (e.g., P+ diffusion regions) of the PFET 106 may be formed on the N-well region 108. Further, a gate stack 121 may be formed between such diffusion regions 118, 120. Further, the substrate 102 may include one or more shallow trench isolation (STI) oxide regions. For example, the substrate 102 may include a first STI oxide region 122 between the first diffusion region 114 of the NFET 104 and the second diffusion region 120 of the PFET 106. A boundary of the N-well region 108 and the buried N-band region 110, and a boundary of the N-well region 108 and the P-well region 112 may be below the first STI oxide region 122. Further, the CMOS device 100 may include a second STI oxide region 124 having a first side adjacent the first diffusion region 118 of the PFET 106. The CMOS device 100 may include another N+ diffusion region 126 adjacent a second side of the second STI oxide region 124. Such a diffusion region may serve to provide contact to the N-well region 108. Further, the CMOS device 100 may include third STI oxide region 128 having a first side adjacent the second diffusion region 116 of the NFET 104. The CMOS device 100 may include another P+ diffusion region 130 adjacent a second side of the third STI oxide region 128. Such a diffusion region 130 may serve to provide contact to the P-well region 112.

The gate stack 117 of the NFET 104 and the gate stack 121 of the PFET 106 may serve as first and second inputs 132, 134 of the CMOS device 100. The first diffusion region 114 of the NFET 104 and the second diffusion region 120 of the PFET 106 may serve as an output 136 of the CMOS device 100. Additionally, the second diffusion region 116 of the NFET 104 and the P+ diffusion region 130 may be coupled to a low voltage such as ground. Further, the first diffusion region 118 of the PFET 106 and the N+ diffusion region 126 may be coupled to a high voltage such as VDD.

Due to the structure of the conventional CMOS device 100, during operation, portions of the CMOS device 100 may serve as or form one or more parasitic bipolar junction transistors (BJTs). For example, during operation a first BJT, such as an npn transistor 138, and a second BJT, such as a pnp transistor 140, may be formed in the CMOS device 100. The npn transistor 138 may have an approximately vertical orientation and the pnp transistor 140 may have an approximately horizontal or lateral orientation. Such transistors 138, 140 may be coupled together into a loop. More specifically, the first diffusion region 114 of the NFET 104 may serve as an emitter 142 of the npn transistor 138. Alternatively, in some embodiments, the second diffusion region 116 may serve as the emitter of the npn transistor 138. Further, the P-well region 112 of the CMOS device 100 may serve as a base 144 and the buried N-band region 110 of the CMOS device 100 may serve as a collector 146 of the npn transistor 138. Similarly, the first diffusion region 118 of the PFET 106 may serve as an emitter 148 of the pnp transistor 140. Alternatively, in some embodiments, the second diffusion region 120 may serve as the emitter 148 of the pnp transistor 140. Further, the N-well region 108 of the CMOS device 100 may serve as a base 150 and the P-well region 112 of the CMOS device 100 may serve as a collector 152 of the pnp transistor 140. Because the collector 146 of the npn transistor 138 and the base 150 of the pnp transistor 140 are coupled together (e.g., shared) and because the base 144 of the npn transistor 138 and collector 152 of the pnp transistor 140 are coupled together (e.g., shared), the parasitic BJTs 138, 140 may be coupled together into a loop (e.g., wired to form a positive feedback configuration).

Additionally, the N-well 108 may serve as a first and second resistive element R1, R2 that may couple the high voltage VDD to the base 150 of the pnp transistor 140. Similarly, the P-well region 112 may serve as a third and fourth resistive element R3, R4 that may couple the base 144 of the npn transistor 138 to ground. Further, the buried N-band region 110 of the CMOS device 100 may serve as fifth resistive element R5 that may couple the collector 146 of the npn transistor 138 to the base 150 of the pnp transistor 140.

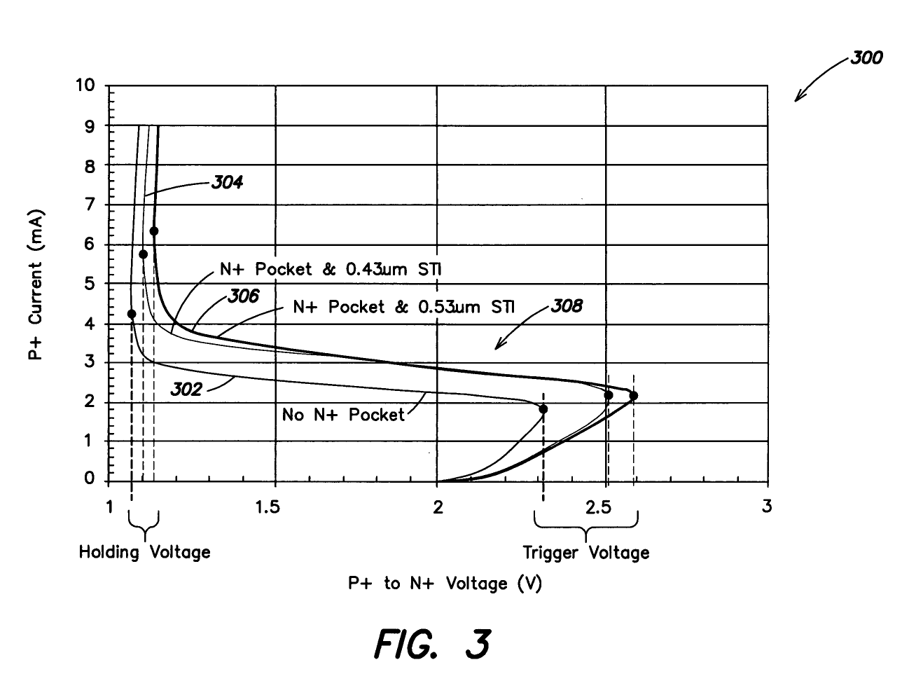

During operation the CMOS device 100 may function as an inverter. However, a disturbance to the CMOS device 100 such as a particle (e.g., ion, cosmic ray and/or the like) that strikes the CMOS device 100, a voltage induced in the CMOS device 100 and/or similar occurrence may initiate a regenerative action in the CMOS device 100. For example, a disturbance such as a heavy ion hit, voltage overshoot on the emitter 148 of the pnp transistor 140 or a voltage undershoot on emitter 142 of npn transistor 138 may result in the onset of regenerative action (illustrated below with reference to FIG. 3) that may cause a negative differential resistance behavior and eventual latchup of the CMOS device 100. The regenerative action may refer to feedback between the npn and pnp transistors 138, 140, which may cause a current induced by the disturbance to increase as the current is provided through the loop. Such a regenerative action may result in latchup. More specifically, due to the increased current, respective bases 144, 150 of the BJTs 138, 140 may be flooded with carriers. Consequently, an extremely low-impedance path may form between respective emitters 142, 148 of BJTs 138, 140. A voltage applied across the CMOS device 100 may be larger than a holding voltage, which defines a threshold at which the CMOS device enters latchup. Once the CMOS device 100 in a state in which the low-impedance path is formed, portions of the device 100 which form the path may lose functionality or be irreversibly damaged. Once the CMOS device 100 enters latchup, the CMOS device 100 may be removed from such state by lowering (e.g., drastically) or removing a voltage (e.g., power supply voltage) applied across the CMOS device 100. However, once the CMOS device enters latchup, irreversible damage occurs almost instantaneously.

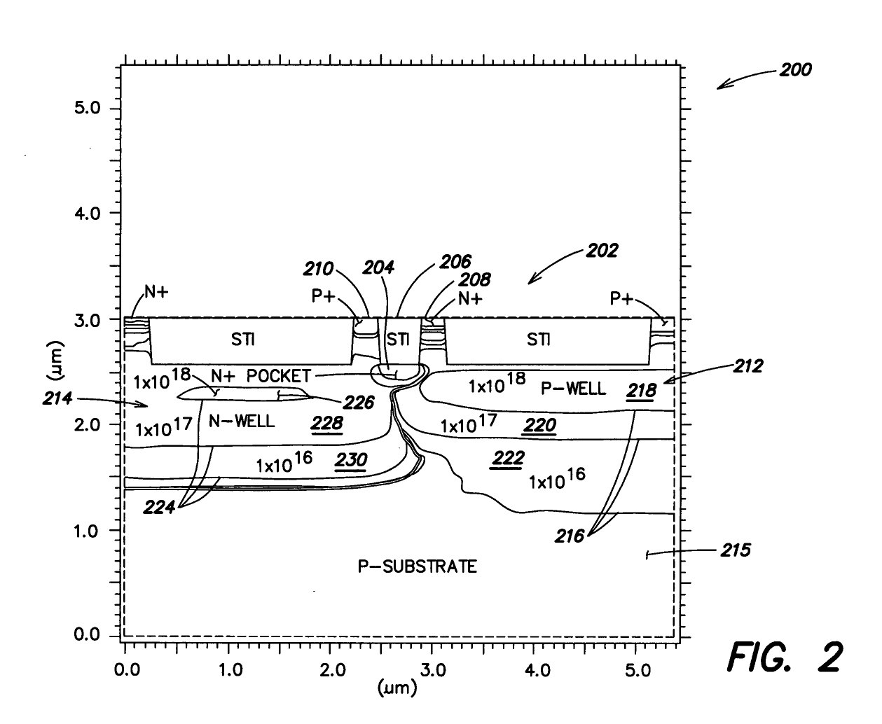

Due to the catastrophic damage caused to semiconductor devices caused by latchup, electrical operational and environmental conditions which may initiate regenerative action which may result in latchup should be avoided. For semiconductor devices employed in mission critical applications, immunity from electrical operational and environmental conditions which may cause latchup should be assured. However, assuring such immunity is difficult (e.g., in applications where a semiconductor device is exposed to harsh environments). For example, in aerospace applications semiconductor devices on a chip may be exposed to high levels of cosmic radiation. The present invention provides a high level of latchup immunity using fundamentally robust bulk CMOS technology. More specifically, the present invention provides structural enhancements, including doping modifications, adapted to reduce and/or prevent latchup that may be applied to existing technologies. Details of the present methods and apparatus are described below with reference to FIGS. 2-14.

FIG. 2 illustrates a simulation 200 of a CMOS device 202 adapted to reduce latchup in accordance with an embodiment of the present invention. With reference to FIG. 2, the CMOS device 202 may be similar to the conventional semiconductor device 100. However, the CMOS device 202 includes a dual-well configuration (e.g., does not include a triple-well design). Alternatively, the CMOS device 202 may have a different configuration. In contrast to the conventional semiconductor device 100, the CMOS device 202 may include a dopant-implanted region or pocket 204 below an STI oxide region 206 which is between respective diffusion regions 208, 210 of an NFET and PFET of the CMOS device 202. For example, the dopant-implanted region or pocket 204 may be formed selectively between a P-well region 212 and an N-well region 214 formed on a bulk substrate 215 (represented as “P-SUBSTRATE”) in FIG. 2. As described in further detail below, the dopant-implanted region or pocket 204 is adapted to reduce and/or prevent latchup. For example, the region or pocket 204 may have a concentration of about 5×10¹⁸ cm⁻³ to about 5×10²⁰ cm⁻³ of N-type dopant (although a larger or smaller and/or different concentration range may be employed). Further, a different and/or additional dopant may be employed. Consequently, as holes pass through the dopant-implanted region or pocket 204 some of the holes may combine with electrons in the dopant-implanted region or pocket 204, thereby reducing carrier lifetime. Therefore, fewer holes may exit the dopant-implanted region or pocket 204 than that which enter the dopant-implanted region or pocket 204. In this manner, a trigger voltage at which regenerative action begins and/or a holding voltage at which latchup occurs may increase.

The simulation 200 further shows a first set of contour lines 216 illustrating dopant concentrations in different portions of the P-well region 212. For example, a first portion 218 of the P-well region 212 may have a concentration of about 1×10¹⁸ cm⁻³, a second portion 220 of the of the P-well region 212 may have a concentration of about 1×10¹⁷ cm⁻³ and a third portion 222 of the P-well region 212 may have a concentration of about 1×10¹⁶ cm⁻³. Similarly, the simulation 200 further shows a second set of contour lines 224 illustrating dopant concentrations in different portions of the N-well region 214. For example, a first portion 226 of the N-well region 214 may have a concentration of about 1×10¹⁸ cm⁻³, a second portion 228 of the of the N-well region 214 may have a concentration of about 1×10¹⁷ cm⁻³ and a third portion 230 of the N-well region 214 may have a concentration of about 1×10^{16 cm}⁻³. However, a different concentration may be employed for any portion 218-222, 226-230 of the P-well and/or N-well region 212, 214. As shown the STI oxide region may be formed to a depth of about 0.45 μm below a top surface of the CMOS device 202 (although the STI oxide region 206 may be formed to a larger or smaller depth). Further, the dimensions of regions of the CMOS device simulation 200 are exemplary, and therefore, different dimensions may be employed.

FIG. 3 is a graph 300 illustrating a relationship between current through a CMOS device adapted to reduce latchup and a voltage applied across the CMOS device in accordance with an embodiment of the invention. With reference to FIG. 3, the graph 300 represents results of simulated operation of a CMOS device adapted to reduce latchup using a TSUPREM4 process model and FIELDAY device model finite element programs. The CMOS device may be similar to the conventional CMOS device 100 but include a dopant-implanted region or pocket as described below. The graph 300 illustrates a relationship between a voltage of the pnp transistor emitter with respect to the npn transistor emitter (P+ to N+ voltage) and current through the emitter of the pnp transistor (P+ current). For example, a first curve 302 illustrates such a relationship for a CMOS device that does not include a dopant-implanted region or pocket. A second curve 304 illustrates such a relationship for a CMOS device having a dopant-implanted region or pocket (e.g., an N+ region or pocket) formed below an STI oxide region to about 0.43 μm below a bottom surface of the STI oxide region and a third curve 306 illustrates such a relationship for a CMOS device having a dopant-implanted region or pocket formed below an STI oxide region to about 0.53 μm below a bottom surface of the STI oxide region.

For each CMOS device, it is assumed an N-well region thereof is biased to a supply voltage VDD while a P-well region and substrate (e.g., bulk silicon region thereof) is biased at ground. An N+ diffusion region, which may serve as a source-drain diffusion of an NFET of the CMOS device, in the P-well region is biased at zero. During operation, as current into a P+ diffusion region of the CMOS device increases (e.g., is ramped up), a point is reached at which the collector-base junction of one of the parasitic bipolars of the CMOS device breaks down, triggering regenerative action. The P+ to N+ voltage at this point is referred to as the trigger voltage. A portion 308 of the graph 300 illustrates a negative incremental resistance caused by positive feedback of the regenerative action. More specifically, the regenerative action decreases a P+ to N+ voltage as the current increases along the negative incremental resistance portion 308 of the characteristic. A P+ to N+ voltage at which each CMOS device enters latchup may be referred to a holding voltage. Once the regenerative action is initiated, latchup may occur within tenths of a nanosecond. If unlimited by external resistance, the current through the CMOS device during latchup may increase without bound and destroy the device. The dopant-implanted region in a CMOS device may increase a voltage (e.g., trigger voltage) at which regenerative action starts (e.g., in response to a disturbance to the CMOS device). Additionally or alternatively, the dopant-implanted region in the CMOS device may increase a voltage (e.g., holding voltage) at which the CMOS device enters latchup.

More specifically, as shown by the first and second curves 302, 304, a dopant-implanted region formed below an STI oxide region formed to a depth of about 0.43 μm below a bottom surface of the STI oxide region may increase a trigger voltage by 200 mV compared to the CMOS device without a dopant-implanted region. Similarly, as shown by the first and third curves 302, 306, a dopant-implanted region formed below an STI oxide region formed to a depth of about 0.53 μm below a bottom surface of the STI oxide region may increase a trigger voltage by 280 mV compared to the CMOS device without a dopant-implanted region. Such an increase in trigger voltage provides a larger voltage range in which regenerative action is not triggered. In this manner, the increase in trigger voltage may reduce and/or eliminate CMOS device latchup.

Additionally or alternatively, as shown by the first and second curves 302, 304, a dopant-implanted region formed below an STI oxide region formed to a depth of about 0.43 μm below the STI oxide region may increase a holding voltage by 36 mV compared to the CMOS device without a dopant-implanted region. Similarly, as shown by the first and third curves 302, 306, a dopant-implanted region formed below an STI oxide region formed to a depth of about 0.53 μm below the STI oxide region may increase a holding voltage by 68 mV compared to the CMOS device without a dopant-implanted region. During operation, by maintaining a power supply voltage applied to a CMOS device below a holding voltage of the device, the CMOS device may avoid latchup. Consequently, the dopant-implanted region of a CMOS device may enable the CMOS device to operate at a larger power supply voltage (compared to a CMOS device without such a dopant-implanted region) which may be more suitable for performance requirements of the CMOS device or circuits comprising the CMOS device. Because a supply voltage VDD of about 1.1 V to about 1.2 V are typically applied to a CMOS device, an improvement of tens of millivolts in holding voltage may be very worthwhile. By increasing a holding voltage and/or a trigger voltage of a CMOS device, the dopant-implanted region may reduce latchup and possibly provide latchup immunity.

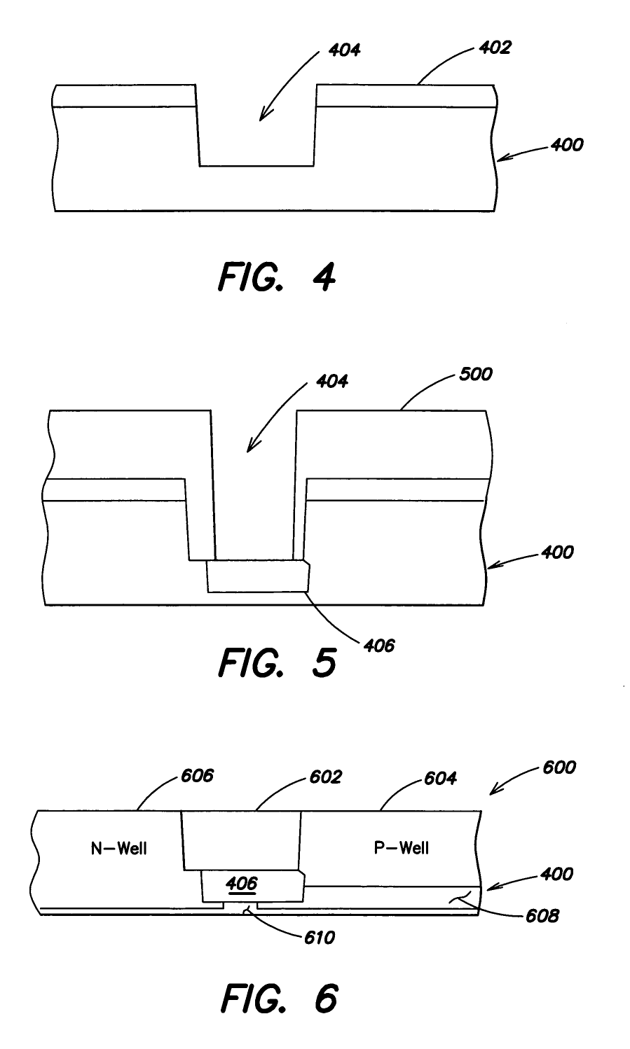

Methods of manufacturing first through third exemplary CMOS devices adapted to reduce latchup are described below with reference to FIGS. 4-14. FIG. 4 is a cross-sectional side view of a substrate 400 following a first step of a method of manufacturing a first exemplary CMOS device adapted to reduce latchup in accordance with an embodiment of the present invention. With reference to FIG. 4, a bulk silicon substrate 400 may be provided. CVD or another suitable method may be employed to deposit a layer of oxide or another suitable material on the substrate 400. The oxide layer may be about 5 nm to about 20 nm thick (although a larger or smaller and/or different thickness range may be employed). Additionally or alternatively, CVD or another suitable method may be employed to deposit a layer of nitride or another suitable material on the substrate 400. The nitride layer may be about 50 nm to about 500 nm thick (although a larger or smaller and/or different thickness range may be employed). In this manner, one or more pad layer 402 may be formed on the substrate 400. RIE or another suitable method may be employed to remove portions of the pad layers 402 and the bulk substrate 400. In this manner, the pad layers 402 may be patterned and a shallow trench 404 (e.g., a shallow isolation trench) may be formed in the substrate 400. The trench 404 may be formed to a depth of about 0.2 μm to about 1 μm and may have a width of about 25 nm to about 1000 nm (although a larger or smaller and/or different depth and/or width range may be employed).

FIG. 5 is a cross-sectional side view of the substrate 400 following a second step of the method of manufacturing the first exemplary CMOS device adapted to reduce latchup in accordance with an embodiment of the present invention. With reference to FIG. 5, a resist (e.g., photoresist) layer may be applied to the substrate 400 and patterned to form a resist block mask 500. In some embodiments, a block mask may be used to define an opening in the resist layer. Portions of the resist block mask 500 may be formed on a top surface of the substrate 400 and along sidewalls of the trench 404. The resist block mask 500 may serve to protect portions of the substrate 400 from subsequent processing (e.g., dopant implantation).

Implantation may be employed to selectively dope portions of the substrate 400. During implantation, the resist block mask 500 may prevent portions of the substrate 400 from being exposed to dopant (e.g., an N+ dopant). For example, portions of the trench 404 protected by resist block mask 500 (e.g., non-opened portions thereof) may not be exposed to the dopant. To wit, portions of the trench 404 not covered by the resist block mask 500 may be implanted with dopant, thereby forming a dopant-implanted region or pocket 406 below the trench 404. The dopant-implanted region or pocket 406 may be adpated to reduce latchup in the manner described above. In some embodiments, the implantation may form an N+ dopant-implanted region or pocket 406 having a peak concentration of about 5×10¹⁸ cm⁻³ to about 5×10²⁰ cm⁻³ to a junction depth of about 0.2 to about 0.3 μm from a bottom surface of the trench 404. However, a larger, smaller and/or different concentration and/or depth range may be employed. Arsenic may be employed as the implantation dopant species to avoid excessive diffusion of the dopant-implanted region or pocket 406. However, a different dopant species, such as phosphorous, antimony and/or the like, may be employed. Conditions employed during implantation may be similar to those employed during standard N+ source/drain implantation (although different conditions may be employed).

It should be noted that a footprint of the dopant-implanted region or pocket 406 may be not be entirely within a footprint of a subsequently-formed oxide-filled STI region (602 in FIG. 6). Alternatively, the footprint of the dopant-implanted region or pocket 406 may be entirely within the footprint of the subsequently-formed oxide-filled STI region 602.

FIG. 6 is a cross-sectional side view of the substrate 400 following a third step of the method of manufacturing the first exemplary CMOS device adapted to reduce latchup in accordance with an embodiment of the present invention. With reference to FIG. 6, a photoresist stripper bath or another suitable method may be employed to remove the resist block mask (500 in FIG. 5) from the substrate 400. Thereafter, standard processing may be employed to finish manufacturing the CMOS device 600. MOSFETs formed on the substrate 400 may be similar to those formed on the conventional CMOS device 100. For convenience, such MOSFETs are not shown in FIG. 6. For example, CVD or another suitable method followed by RIE or another suitable method may be employed fill the trench (404 in FIG. 5) with oxide or another suitable material such that an STI oxide region 602 may be formed on the substrate 400. Thereafter, RIE or another suitable method may be employed to remove the pad layers (402 in FIG. 4) from the substrate 400. Further, one or more implantation steps may be employed to form a P-well region 604 and an N-well region 606 on the substrate 400 such that the dopant-implanted region 406 is below the STI oxide region 602 and between the P-well and N-well regions 604, 606. Additionally, in some embodiments such as those in which an isolated P-well region 604 is desired (e.g., triple-well structures), deep implantation of an N-type dopant may be employed to form an N-band region 608 below the P-well region 604 adapted to isolate the P-well region 604 from bulk silicon 610 of the substrate 400.

Subsequently, standard processing known to one of skill in the art may be employed to complete manufacturing the CMOS device 600 on the substrate 400 (e.g., a chip). For example, implantation may be employed to dope one or more regions of the substrate 400 such that a threshold voltage of one or more transistors of the CMOS device may be affected. Additionally, a gate dielectric for a transistor included in the CMOS device 600 may be formed. Further, a gate conductor may be formed (e.g., deposited and patterned) for a transistor of the CMOS device 600. Implantation may be employed to form source/drain diffusion regions of each transistor of the CMOS device 600. Additionally, standard processing may be employed to form one or more vias, contacts, interlevel dielectric layers and metal wiring layers on the substrate 400. In this manner, the first exemplary CMOS device 600 including a dopant-implanted region 406 adapted to reduce and/or eliminate latchup in the manner described above may be formed. To form the first exemplary CMOS device 600, the resist block mask 500 may be employed to define portions of the trench 404 through which dopant employed to form the dopant-implantation region 406 passes. An STI oxide region 602, which is between the subsequently-formed P-well and N-well regions 604, 606 may be formed in the trench 404.

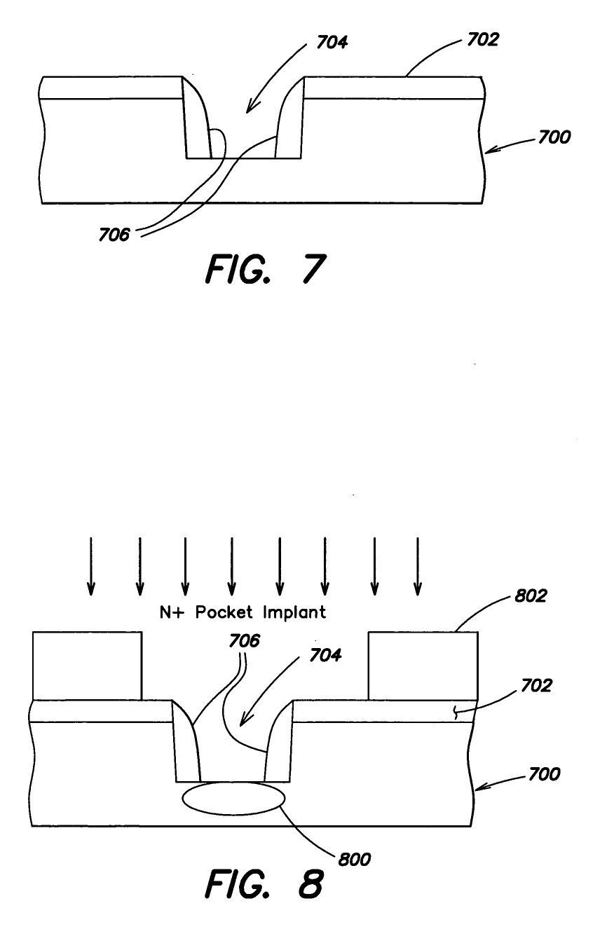

The present invention may include additional CMOS devices adapted to reduce and/or prevent latchup and methods of manufacturing the same. For example, FIG. 7 is a cross-sectional side view of the substrate 700 following a first step of a method of manufacturing a second exemplary CMOS device adapted to reduce latchup in accordance with an embodiment of the present invention. Steps of manufacturing the second exemplary CMOS device may be similar to steps of manufacturing the first exemplary CMOS device 400 through that described with reference to FIG. 1. More specifically, a bulk silicon substrate 700 may be provided. CVD or another suitable method may be employed to deposit a layer of oxide or another suitable material on the substrate 700. Additionally or alternatively, CVD or another suitable method may be employed to deposit a layer of nitride or another suitable material on the substrate 700. In this manner, one or more pad layers 702 may be formed on the substrate 700. RIE or another suitable method may be employed to remove portions of the pad layers 702 and the bulk substrate 700. In this manner, the pad layers 702 may be patterned and a shallow trench 704 (e.g., a shallow isolation trench) may be formed in the substrate 700. The trench 704 may be formed to a depth of about 0.2 μm to about 1 μm and may have a width of about 25 nm to about 1000 nm (although a larger or smaller and/or different depth and/or width range may be employed). In contrast to the method of manufacturing the first exemplary CMOS device 400, during the method of manufacturing the second exemplary CMOS device, CVD or another suitable method may be employed to deposit a conformal layer of germanium or the like on the substrate 700 followed by RIE or another suitable method to remove portions of such layer, thereby forming spacers 706 (e.g., germanium spacers) along sidewalls of the trench 704. The spacers 706 may be about 10 nm to about 200 nm wide (although a larger or smaller and/or different width range may be employed). Germanium may be employed as the spacer material, because germanium may be selectively removed from the substrate with ease during subsequent processing (e.g., after substrate implantation to form a dopant-implantation region). However, a different and/or additional material may be employed to form the spacers 706. Additionally, in some embodiments, such spacers 706 may not be removed from the substrate 700. For example, the spacers 706 may be formed from SiO₂ or another suitable material and may be left in place to serve as a portion of material employed to fill the trench 704 during subsequent processing (e.g., processing after substrate implantation).

FIG. 8 is a cross-sectional side view of the substrate 700 following a second step of the method of manufacturing the second exemplary CMOS device adapted to reduce latchup in accordance with an embodiment of the present invention. With reference to FIG. 8, a resist (e.g., photoresist) layer may be applied to the substrate 700 and patterned to form a resist block mask 802. In some embodiments, a block mask may be used to define an opening in the resist layer. The resist block mask 802 (along with the pad layers 702 and the spacers 706) may serve to protect portions of the substrate 700 from subsequent processing (e.g., dopant implantation) while exposing a portion of the trench 704 during the subsequent processing. In contrast to the resist block mask 500 formed during the method of manufacturing the first exemplary CMOS device, the resist block mask 802 may be non-critical. For example, the resist block mask 802 may be adapted to cover portions of the substrate 700 that are not to receive subsequently-implanted dopant, and therefore may not be formed to an edge of sidewalls of the trench 704. However, the pad layers 702 and spacers 706 may protect some portions of the substrate 700 exposed by resist block mask 802 from subsequent processing such as dopant implantation.

Similar to the implantation step described above with reference to FIG. 5, during the method of manufacturing the second exemplary CMOS device, implantation may be employed to selectively dope portions of the substrate 700. More specifically, portions of the trench 704 not covered by the resist block mask 802 may be implanted with dopant, thereby forming a dopant-implanted region or pocket 800 below the trench 704. The dopant-implanted region or pocket 800 may be adapted to reduce latchup in the manner described above. Implant conditions employed during the method of manufacturing the second exemplary CMOS device may be the same as or similar to conditions employed during the method of manufacturing the first exemplary CMOS device 100.

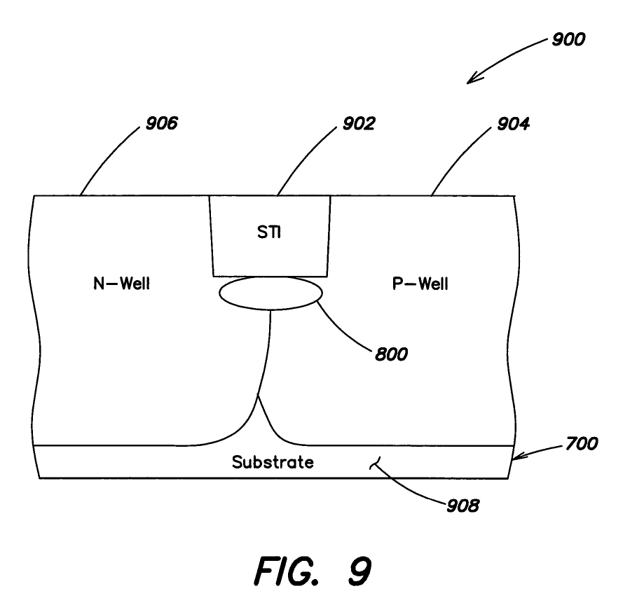

It should be noted that a footprint of the dopant-implanted region or pocket 800 may be entirely within a footprint of a subsequently-formed oxide-filled STI region (902 in FIG. 9). Alternatively, the footprint of the dopant-implanted region or pocket 800 may not be entirely within the footprint of the subsequently-formed oxide-filled STI region 902.

FIG. 9 is a cross-sectional side view of the substrate following a third step of the method of manufacturing a second exemplary CMOS device adapted to reduce latchup in accordance with an embodiment of the present invention. With reference to FIG. 9, a photoresist stripper bath or another suitable method may be employed to remove the resist block mask (802 in FIG. 8) from the substrate 700. Thereafter, standard processing may be employed to finish manufacturing the CMOS device 900. MOSFETs formed on the substrate 700 may be similar to those formed on the conventional CMOS device 100. For convenience, such MOSFETs are not shown in FIG. 9. For example, CVD or another suitable method followed by RIE or another suitable method may be employed to fill the trench (704 in FIG. 8) with oxide or another suitable material such that an STI oxide region 902 may be formed on the substrate 700. Thereafter, RIE or another suitable method may be employed to remove the pad layers (702 in FIG. 8) and possibly portions of the spacers (706 in FIG. 8) from the substrate 700. Further, one or more implantation steps may be employed to form a P-well region 904 and an N-well region 906 on the substrate 700 such that the dopant-implanted region 800 is below the STI oxide region 902 and between the P-well and N-well regions 904, 906. Additionally, in some embodiments such as those in which an isolated P-well region is desired (e.g., triple-well structures), deep implantation of an N-type dopant may be employed to form an N-band region (not shown) below the P-well region 904 adapted to isolate the P-well region 904 from bulk silicon 908 of the substrate 700. Subsequently, standard processing known to one of skill in the art may be employed to complete manufacturing the CMOS device 900 on the substrate 700 (e.g., a chip) similar to that described above with reference to FIG. 6.

In this manner, the second exemplary CMOS device 900 including a dopant-implanted region 800 adapted to reduce and/or eliminate latchup in the manner described above may be formed. To form the second exemplary CMOS device 900, the spacers (706 in FIG. 8) may be employed to define portions of the trench (704 in FIG. 8) through which dopant employed to form the dopant-implantation region 800 passes. An STI oxide region 902, which is between the subsequently-formed P-well region and N-well regions 904-906, may be formed in the trench (704 in FIG. 8). The spacers 706 may accommodate for alignment tolerance of the resist block mask (802 in FIG. 8). More specifically, the spacers 706 may enable a footprint of the dopant-implanted region 800 resulting from implantation to be formed within a footprint of the STI oxide region 902. For example, the dopant-implanted region 800 may be centered below the STI oxide region 902. By preventing the footprint of the dopant-implanted region 800 from extending beyond the footprint of the STI oxide region 902, a leakage current forming between the dopant-implanted region 800 and N+ diffusion regions at a surface of the P-well 904 may be reduced and/or eliminated.

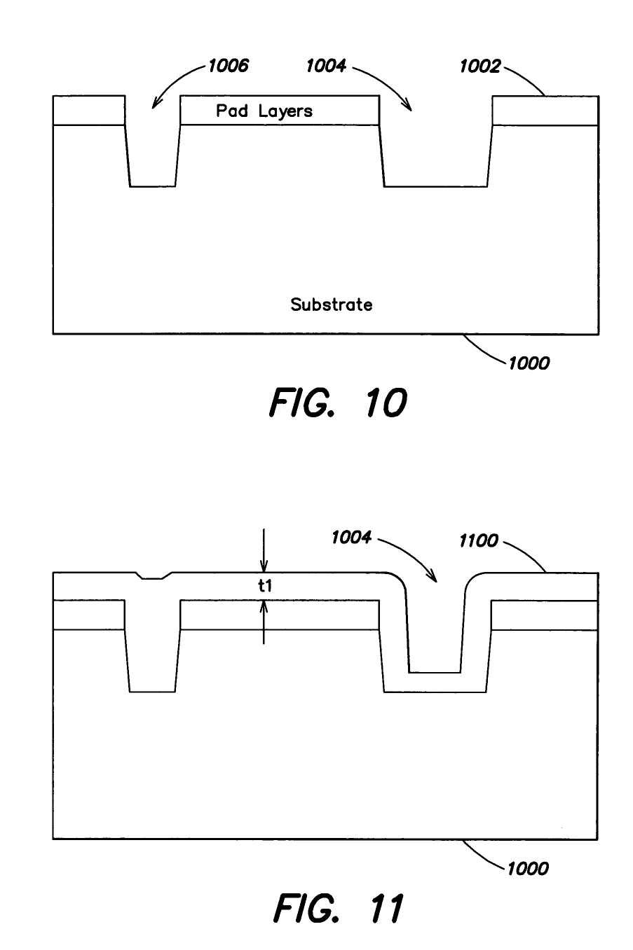

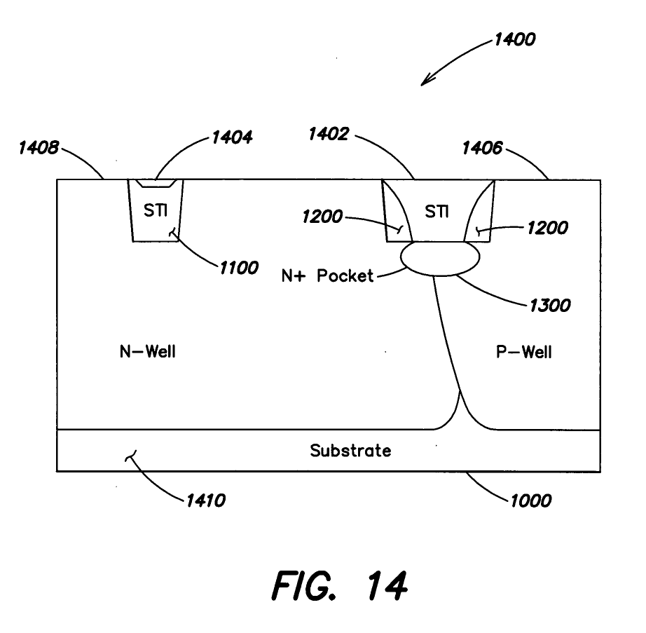

The present invention may include additional CMOS devices adapted to reduce and/or prevent latchup and methods of manufacturing the same. For example, FIG. 10 is a cross-sectional side view of the substrate following a first step of a method of manufacturing a third exemplary CMOS device adapted to reduce latchup in accordance with an embodiment of the present invention. With reference to FIG. 10, a bulk silicon substrate 1000 may be provided. CVD or another suitable method may be employed to deposit a layer of oxide or another suitable material on the substrate 1000. The oxide layer may be about 5 nm to about 20 nm thick (although a larger or smaller and/or different thickness range may be employed). Additionally or alternatively, CVD or another suitable method may be employed to deposit a layer of nitride or another suitable material on the substrate 1000. The nitride layer may be about 50 nm to about 500 nm thick (although a larger or smaller and/or different thickness range may be employed). In this manner, one or more pad layers 1002 may be formed on the substrate 1000. RIE or another suitable method may be employed to remove portions of the pad layers 1002 and the bulk substrate 1000 such that at least one wide shallow trench 1004 (only one shown) and at least one narrower shallow trench 1006 (only one shown) may be formed on the substrate 1000. A wide trench 1004 may be formed into an oxide STI region between a P-well region and N-well region on the substrate 1000 during subsequent processing. In some embodiments, the wide trench 1004 may have a width of about 200 nm to about 1000 nm and the narrow trench 1006 may have a width of about 22 nm to about 90 nm (although a larger or smaller and/or different width range may be for the wide trench 1004 and/or narrow trench 1006). In this manner, the present method may form a shallow trench 1004 that is considerably wider than a standard trench (e.g., the narrow trench 1006) located between an N-well and a P-well region where latchup reduction may be desired. By forming the wide trench 1004 device density on the substrate 1000 may be reduced. However, as described below, by employing the wide trench 1004, the present method may avoid using a mask to form the third exemplary CMOS device 1400 in FIG. 14. A narrow trench 1006 may be located anywhere else on the substrate 1000.

FIG. 11 is a cross-sectional side view of the substrate 1000 following a second step of the method of manufacturing the third exemplary CMOS device adapted to reduce latchup in accordance with an embodiment of the present invention. With reference to FIG. 11, CVD or another suitable method may be employed to form a conformal layer 1100 of oxide or another suitable material on the substrate 1000. A thickness of the oxide layer 1100 may be adjusted such that a narrow STI region (e.g., narrow trench (1006 in FIG. 10)) is substantially filled, while the wide STI region (e.g., wide trench 1004)) is only conformably coated. For example, the widths of the narrow trench (1006 in FIG. 10), wide trench (1004 in FIG. 10) and a thickness t1 of the oxide layer 1100 may be selected such that the thickness t1 of the oxide layer 1100 may be greater than or equal to half the width of the narrow trench 1006 and less than half the width of the wide trench 1004. Therefore, the conformal layer 1100 of oxide may completely fill the narrow trench 1006 while forming along sidewalls and a bottom surface of the wide trench without completely filling the wide trench 1004.

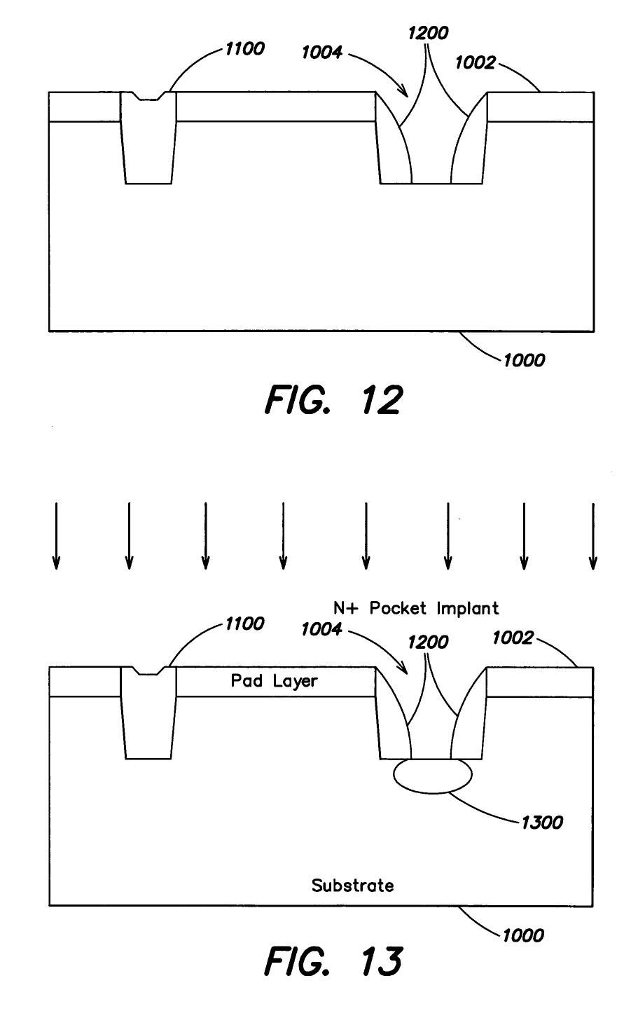

FIG. 12 is a cross-sectional side view of the substrate 1000 following a third step of the method of manufacturing the third exemplary CMOS device adapted to reduce latchup in accordance with an embodiment of the present invention. With reference to FIG. 12, RIE or another suitable method may be employed remove portions of the oxide layer 1100 such that spacers 1200 are formed along sidewalls of the wide trenches 1004 while oxide in the narrow trench (1006 in FIG. 10) may only be recessed below the top surface of the pad layer 1002.

FIG. 13 is a cross-sectional side view of the substrate 1000 following a fourth step of the method of manufacturing the third exemplary CMOS device adapted to reduce latchup in accordance with an embodiment of the present invention. With reference to FIG. 13, similar to the implantation step described above with reference to FIG. 5, during the method of manufacturing the third exemplary CMOS device, implantation may be employed to selectively dope portions of the substrate 1000. More specifically, portions of the wide trench 1004 not covered by the spacers 1200 may be implanted with dopant, thereby forming a dopant-implanted region or pocket 1300 (e.g., an N+ dopant-implanted region or pocket) below the trench 1004. The dopant-implanted region or pocket 1300 may be adapted to reduce latchup in the manner described above. Portions of the oxide layer 1100 filling (e.g., plugging) the narrow trenches (1006 in FIG. 10) may prevent dopant implantation below the narrow trenches 1006. Implant conditions employed during the method of manufacturing the third exemplary CMOS device may be the same as or similar to conditions employed during the method of manufacturing the first exemplary CMOS device 600 and/or the second exemplary CMOS device 900.

It should be noted that a footprint of the dopant-implanted region or pocket 1300 may be entirely within a footprint of a subsequently-formed oxide-filled STI region (1402 in FIG. 14). Alternatively, the footprint of the dopant-implanted region or pocket 1300 may not be entirely within the footprint of the subsequently-formed oxide-filled STI region 1402.

FIG. 14 is a cross-sectional side view of the substrate 1000 following a fifth step of the method of manufacturing the third exemplary CMOS device 1400 adapted to reduce latchup in accordance with an embodiment of the present invention. With reference to FIG. 14, RIE or another suitable method may be employed to remove the pad layers (1002 in FIG. 12) and portions of the oxide layer 1100, including portions of the spacers 1200 formed thereby, from the substrate 1400. Standard processing may be employed to finish manufacturing the CMOS device 1000. MOSFETs formed on the substrate 1000 may be similar to those formed on the conventional CMOS device 100. For convenience, such MOSFETs are not shown in FIG. 14. For example, CVD or another suitable followed by RIE or another suitable method may be employed fill the wide and/or narrow trenches (1004, 1006 in FIG. 10) with oxide or another suitable material such that STI oxide regions 1402, 1404 may be formed on the substrate 1000. In some embodiments, the oxide layer 1100, including the spacers 1200 formed thereby, may be left in place during the STI fill operation to form the STI oxide regions 1402, 1404. Alternatively, in some other embodiments, the oxide layer 1100, including the spacers 1200 formed thereby, may be removed from the substrate 1000 before the STI fill operation. More specifically, in such embodiments, RIE or another suitable method may be employed to remove the oxide layer 1100, including spacers 1200 formed thereby, from the substrate 1000. Thereafter, for example, CVD followed by RIE may be employed fill the wide and/or narrow trenches (1004, 1006 in FIG. 10) with oxide or another suitable material such that the STI oxide regions 1402, 1404 may be formed on the substrate 1000.

Further, one or more implantation steps may be employed to form a P-well region 1406 and an N-well region 1408 on the substrate 1000 such that the dopant-implanted region or pocket 1300 is below the STI oxide region 1402 and between the P-well and N-well regions 1406, 1408. Additionally, in some embodiments such as those in which an isolated P-well region 1406 is desired (e.g., triple-well structures), deep implantation of an N-type dopant may be employed to form an N-band region (not shown) below the P-well region 1406 adapted to isolate the P-well region 1406 from bulk silicon 1410 of the substrate 1000.

Subsequently, standard processing known to one of skill in the art may be employed to complete manufacturing the CMOS device 1400 on the substrate 1000 (e.g., a chip). For example, implantation may be employed to dope one or more regions of the substrate 1000 such that a threshold voltage of one or more transistors of the CMOS device 1400 may be affected. Additionally, a gate dielectric for a transistor included in the CMOS device 1400 may be formed. Further, a gate conductor may be formed (e.g., deposited and patterned) for a transistor of the CMOS device 1400. Implantation may be employed to form source/drain diffusion regions of each transistor of the CMOS device 1400. Additionally, standard processing may be employed to form one or more vias, contacts, interlevel dielectric layers and metal wiring layers on the substrate 1000. In this manner, the third exemplary CMOS device 1400 including a dopant-implanted region or pocket 1300 adapted to reduce and/or eliminate latchup in the manner described above may be formed. To form the third exemplary CMOS device 1400, spacers 1200 formed along sidewalls of the wide trench 1004 may be used to define portions of the wide trench 1004 through which dopant employed to form the dopant-implantation region 1300 passes. An STI oxide region 1402, which is between the subsequently-formed P-well region 1406 and N-well region 1408, may be formed in the wide trench 1004. In contrast to the methods of manufacturing the first and second exemplary CMOS devices 600, 900, the method of manufacturing the third exemplary CMOS device 1400 is maskless. More specifically, the present method does not employ a block mask but rather sidewall spacers 1200 to define the dopant-implanted region 1300 which is below an STI oxide region 1402 and in between wells 1406, 1408.

The present invention provides a CMOS device 600, 900, 1400 adapted to mitigate and/or eliminate latchup and method of manufacturing the same. More specifically, the CMOS device 600, 900, 1400 includes an dopant-implanted region 406, 800, 1300 below an STI oxide region that is between wells. Such a dopant-implanted region 406, 800, 1300 may increase base width of a parasitic pnp transistor 140 which forms in the CMOS device 600, 900, 1400 during operation. Additionally or alternatively, the dopant-implanted region 406, 800, 1300 may reduce carrier lifetime therein. The shorter carrier lifetime and/or increased base width may reduce a beta, and therefore, a gain of the parasitic pnp transistor 140. Consequently, the dopant-implanted region 406, 800, 1400 may reduce a gain of the BJT loop and increase a holding voltage and/or trigger voltage of the CMOS device 600, 900, 1400, thereby reducing and/or eliminating latchup. The present methods and apparatus may be useful applications such as aerospace, defense and/or the like, in which latchup immunity is essential. Further, the present invention provides cost-effective CMOS devices in bulk technology which are adapted to improve latchup immunity. More specifically, the present methods and apparatus formed thereby may avoid complexity and cost associated with conventional methods and apparatus for reducing latchup, such as CMOS devices including locally-deeper STI regions including a doped polysilicon fill.

The foregoing description discloses only exemplary embodiments of the invention. Modifications of the above disclosed apparatus and methods which fall within the scope of the invention will be readily apparent to those of ordinary skill in the art. For instance, although the CMOS devices 600, 900, 1400 described above are inverters, the present invention includes CMOS devices that may perform different logic functions and methods of manufacturing the same.

Accordingly, while the present invention has been disclosed in connection with exemplary embodiments thereof, it should be understood that other embodiments may fall within the spirit and scope of the invention, as defined by the following claims.

The invention claimed is:

1. A semiconductor device on a substrate, comprising:
a shallow trench isolation (STI) oxide region;
a first metal-oxide-semiconductor field-effect transistor (MOSFET) coupled to a first side of the STI oxide region;
a second MOSFET coupled to a second side of the STI oxide region, wherein portions of the first and second MOSFETs form first and second bipolar junction transistors (BJTs) which are coupled into a loop; and
a dopant-implanted region below the STI oxide region, wherein the dopant-implanted region forms a portion of the BJT loop and is adapted to reduce a gain of the loop.

2. The semiconductor device of claim 1 wherein the dopant-implanted region includes a concentration of about 5 ×10¹⁸ cm⁻³ to about 5×10²⁰ cm⁻³ of an n-type dopant.

3. The semiconductor device of claim 1 wherein the dopant-implanted region is formed to a depth of about 0.2 μm to about 0.3 μm from a bottom surface of the STI oxide region.

4. The semiconductor device of claim 1 wherein a footprint of the dopant-implanted region is entirely within a footprint of the STI oxide region.

5. The semiconductor device of claim 1 wherein a footprint of the dopant-implanted region in not entirely within a footprint of the STI oxide region.

6. The semiconductor device of claim 1 wherein:
the first BJT is an npn transistor and the second BJT is a pnp transistor; and
the dopant-implanted region is adapted to increase a width of a base of the pnp transistor.

7. The semiconductor device of claim 1 wherein:
the first BJT is an npn transistor and the second BJT is a pnp transistor; and
the dopant-implanted region is adapted to decrease carrier lifetime in the loop.

8. A substrate, comprising:
a bulk silicon layer; and
a semiconductor device portions of which are formed in the bulk silicon layer, the semiconductor device having:
a shallow trench isolation (STI) oxide region;
a first metal-oxide-semiconductor field-effect transistor (MOSFET) coupled to a first side of the STI oxide region;
a second MOSFET coupled to a second side of the STI oxide region, wherein portions of the first and second MOSFETs form first and second bipolar junction transistors (BJTS) which are coupled into a loop; and
a dopant-implanted region below the STI oxide region, wherein the dopant-implanted region forms a portion of the BJT loop and is adapted to reduce a gain of the loop.

9. The substrate of claim 8 wherein the dopant-implanted region of the semiconductor device includes a concentration of about 5×10¹⁸ cm⁻³ to about 5×10²⁰ cm⁻³ of an n-type dopant.

10. The substrate of claim 8 wherein the dopant-implanted region of the semiconductor device is formed to a depth of about 0.2 μm to about 0.3 μm from a bottom surface of the STI oxide region.

11. The substrate of claim 8 wherein a footprint of the dopant-implanted region is entirely within a footprint of the STI oxide region.

12. The substrate of claim 8 wherein a footprint of the dopant-implanted region in not entirely within a footprint of the STI oxide region.

13. A method of manufacturing a semiconductor device on a substrate, comprising:
forming a shallow trench isolation (STI) oxide region on the substrate;
forming a first metal-oxide-semiconductor field-effect transistor (MOSFET) coupled to a first side of the STI oxide region;
forming a second MOSFET coupled to a second side of the STI oxide region, wherein portions of the first and second MOSFETs form first and second bipolar junction transistors (BJTs) which are coupled into a loop; and
forming a dopant-implanted region below the STI oxide region, wherein the dopant-implanted region forms a portion of the BJT loop and is adapted to reduce a gain of the loop.

14. The method of claim 13 wherein forming the dopant-implanted region includes implanting a concentration of about 5×10¹⁸ cm⁻³ to about 5×10²⁰ cm⁻³ of an n-type dopant into the substrate.

15. The method of claim 13 wherein forming the dopant-implanted region includes forming the dopant-implanted region to a depth of about 0.2 μm to about 0.3 μm from a bottom surface of the STI oxide region.

16. The method of claim 13 wherein:
forming the STI oxide region on the substrate includes forming an isolation trench in the substrate; and
forming the dopant-implanted region includes:
forming a mask on the substrate and along sidewalls of the isolation trench; and
implanting a concentration of about 5×10¹⁸ cm⁻³ to about 5×10²⁰ cm⁻³ of an n-type dopant into the substrate.

17. The method of claim 13 wherein:
forming the STI oxide region on the substrate includes forming an isolation trench in the substrate; and
forming the dopant-implanted region includes:
forming spacers along sidewalls of the isolation trench;
forming a mask on the substrate; and
implanting a concentration of about 5×10¹⁸ cm⁻³ to about 5×10²⁰ cm⁻³ of an n-type dopant into the substrate.

18. The method of claim 17 wherein forming the dopant-implanted region includes forming one or more of an oxide layer and a nitride layer on the substrate.

19. The method of claim 13 wherein:
forming the STI oxide region on the substrate includes forming a first and second isolation trenches on the substrate, wherein the first isolation trench is wider than the second isolation trench; and
forming the dopant-implanted region includes:
forming a conformal oxide layer on the substrate such that oxide is formed along sidewalls and a bottom of the first trench and oxide fills the second trench;
forming spacers along sidewalls of the first trench by removing portions of the oxide layer; and
implanting a concentration of about 5×10¹⁸ cm⁻³ to about 5×10²⁰ cm⁻³ of an n-type dopant into the substrate.

20. The method of claim 19 wherein forming the dopant-implanted region includes forming one or more of an oxide layer and a nitride layer on the substrate.
